(19) United States
(12) Patent Application Publication
(10) Pub. No.: US 2021/0376567 A1
(43) Pub. Date: Dec. 2, 2021

(54) WAVELENGTH-TUNABLE LIGHT SOURCE DEVICE AND WAVELENGTH-TUNABLE LASER ELEMENT CONTROL METHOD

(71) Applicant: FURUKAWA ELECTRIC CO., LTD., Tokyo (JP)

(72) Inventors: Masayoshi KIMURA, Tokyo (JP); Kei TAKAHASHI, Tokyo (JP)

(73) Assignee: FURUKAWA ELECTRIC CO., LTD., Tokyo (JP)

(21) Appl. No.: 17/445,019

(22) Filed: Aug. 13, 2021

Related U.S. Application Data
(63) Continuation of application No. PCT/JP2020/005374, filed on Feb. 12, 2020.

(30) Foreign Application Priority Data
Feb. 14, 2019 (JP) 2019-024949

(51) Int. Cl. H01S 5/062; H01S 5/0687; H01S 5/125; H01S 5/0683

(52) U.S. Cl. CPC H01S 5/062; H01S 5/06837; H01S 5/125; H01S 5/0687

(57) ABSTRACT

A wavelength-tunable light source device includes: a wavelength-tunable laser element including: a laser resonator having two reflecting mirrors having respective periodic peaks of reflection spectrums with respect to wavelength, cycles of the periodic peaks being different from each other; a gain unit in the laser resonator; and a plurality of control elements that control respective laser emission wavelengths in response to electric power supplied thereto; and a control unit that controls the electric power supplied to the control elements. Further, the control elements set, on a basis of the electric power, respective at least wavelength positions where the reflection spectrums of the two reflecting mirrors peak, and the control unit controls the control elements by setting, as sequential control targets, wavelength corresponding control set values, which correspond to discrete intermediate wavelengths between a current laser emission wavelength and a target wavelength.

### CROSS-REFERENCE TO RELATED APPLICATION(S)

This application is a continuation of International Application No. PCT/JP2020/005374, filed on Feb. 12, 2020 which claims the benefit of priority of the prior Japanese Patent Application No. 2019-024949, filed on Feb. 14, 2019, the entire contents of which are incorporated herein by reference.

### BACKGROUND

The present disclosure relates to a wavelength-tunable light source device and a wavelength-tunable laser element control method.

Wavelength-tunable laser elements used in optical communications and configured to have their laser emission wavelength tunable by utilization of the Vernier effect have been disclosed (Japanese Laid-open Patent Publication No. 2016-178283). In such a wavelength-tunable laser element, its wavelength characteristics are changed by heating its wavelength-characteristic-tunable elements, such as a diffraction grating and a ring resonator, using a heater, and its laser emission wavelength is thereby changed. In addition, a semiconductor optical amplifier may be integrated into the wavelength-tunable laser element.

Techniques for tuning the laser emission wavelength of wavelength-tunable laser elements have also been disclosed (Japanese Patent Nos. 6241931 and 6382506). The technique of finely turning the laser emission wavelength may be referred to as a Fine Tuning Frequency (FTF).

### SUMMARY

There is a need for providing a wavelength-tunable light source device and a wavelength-tunable laser element control method that enable the laser emission wavelength to be changed monotonously and stably when the laser emission wavelength is tuned.

According to an embodiment, a wavelength-tunable light source device includes: a wavelength-tunable laser element including a laser resonator having two reflecting mirrors having respective periodic peaks of reflection spectrums with respect to wavelength, cycles of the periodic peaks being different from each other; a gain unit arranged in the laser resonator; and a plurality of control elements that control respective laser emission wavelengths in response to electric power supplied to the control elements; and a control unit, including an arithmetic unit and a recording unit, that controls the electric power supplied to the control elements. Further, the control elements set, on a basis of the electric power, respective wavelength positions where the reflection spectrums of at least two reflecting mirrors peak are, and the control unit controls the control elements by setting, as sequential control targets, wavelength corresponding control set values, which correspond to discrete intermediate wavelengths between a current laser emission wavelength and a target wavelength.

According to an embodiment, a wavelength-tunable light source device includes: a wavelength-tunable laser element including: a laser resonator formed of two reflecting mirrors having reflection spectra with periodic peaks on cycles different from each other in relation to wavelength; a gain unit arranged in the laser resonator; and plural control elements that control laser emission wavelength by being supplied with electric power; and a control unit that includes an arithmetic unit and a recording unit and controls the electric power supplied to the plural control elements. Further, the control unit controls the plural control elements to monotonously change the laser emission wavelength from a current laser emission wavelength to a target wavelength and when monotonously changing the laser emission wavelength, controls the electric power such that a shift between reflection peaks of the two reflecting mirrors is equal to or less than a half width at half maximum of a narrower one of half widths at half maximum of the reflection peaks of the two reflecting mirrors.

According to an embodiment, a control method for a wavelength-tunable laser element and executed by a control unit including an arithmetic unit and a recording unit, the wavelength-tunable laser element including: a laser resonator formed of two reflecting mirrors having reflection spectra with periodic peaks on cycles different from each other in relation to wavelength; a gain unit arranged in the laser resonator; and plural control elements that control laser emission wavelength by being supplied with electric power, the control method including: a setting process of respectively setting, at the plural control elements, on a basis of the electric power supplied, wavelength positions where the reflection spectra of at least two reflecting mirrors peak; and a control process of controlling the plural control elements by sequentially setting control targets that are wavelength corresponding control set values corresponding to discrete intermediate wavelengths between a current laser emission

### BRIEF DESCRIPTION OF THE DRAWINGS

FIG. 1 is a diagram illustrating a schematic configuration of a wavelength-tunable light source device according to an embodiment;

FIG. 2 is a diagram for explanation of tuning of laser emission wavelength;

FIG. 3 is a diagram illustrating an example of relations between DBR power, RING power, and the laser emission wavelength;

FIG. 4 is a diagram for explanation of wavelength monitoring using two ring resonator optical filters;

FIG. 5 is a diagram illustrating an example of control of heater power in a first control example;

FIG. 6 is a diagram illustrating a control flow of the first control example;

FIG. 7 is a diagram illustrating an example of control of heater power in a second control example;

FIG. 8 is a diagram illustrating a control flow of a third control example;

FIG. 9 is a diagram illustrating a control flow of a fourth control example;

FIG. 10 is a diagram for explanation of control of wavelength in a fifth control example; and

FIG. 11 is a diagram illustrating a control flow of a sixth control example.

### DETAILED DESCRIPTION

In the related art, when the laser emission wavelength is finely tuned in a state where a laser light beam is being output in particular, the laser emission wavelength is desirably changed monotonously and stably and is preferably not changed instantaneously or unstably.

Embodiments of the present disclosure will be described in detail below while reference is made to the appended drawings. The present disclosure is not limited by the embodiments described below. Furthermore, the same reference sign will be assigned to elements that are the same or corresponding to each other, as appropriate, throughout the drawings.

### Embodiment

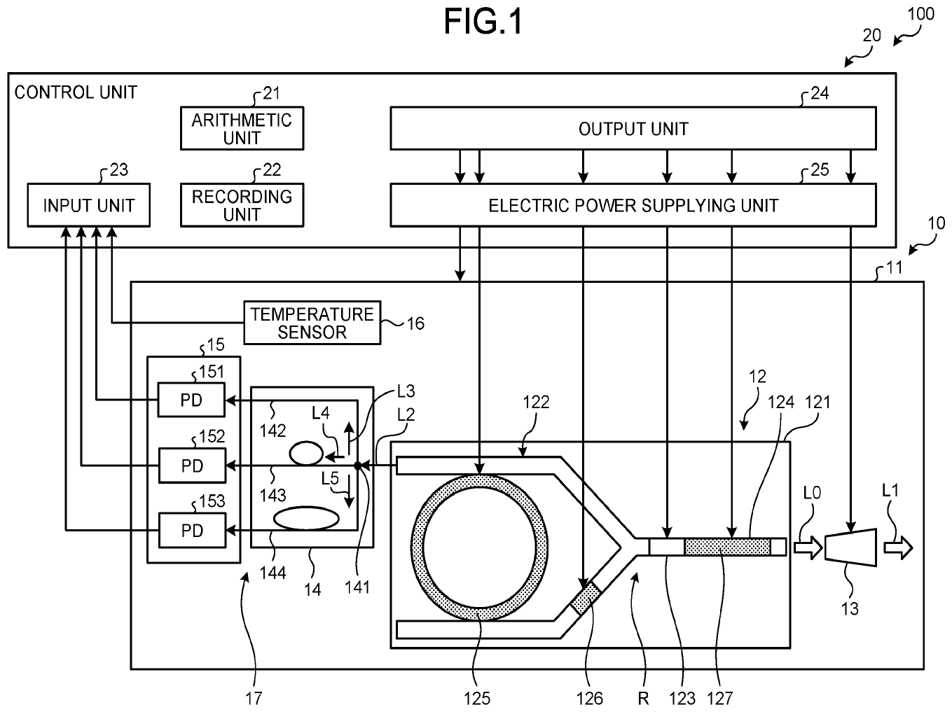

FIG. 1 is a diagram illustrating a configuration of a wavelength-tunable light source device according to an embodiment. This wavelength-tunable light source device 100 includes a wavelength-tunable laser unit 10 and a control unit 20.

The wavelength-tunable laser unit 10 has a configuration with a wavelength-tunable laser element 12, a semiconductor optical amplifier 13, a planar lightwave circuit (PLC) 14, a photodetector 15, and a temperature sensor 16 that are mounted on a Peltier element 11 which is a thermoelement.

The wavelength-tunable laser element 12 is a Vernier-type wavelength-tunable laser element disclosed in Japanese Laid-open Patent Publication No. 2016-178283, for example. The wavelength-tunable laser element 12 has a configuration with a first reflecting mirror 122, a gain unit 123, and a second reflecting mirror 124 that are integrated onto a substrate 121. The first reflecting mirror 122 is a ring resonator mirror with a reflection spectrum having periodic peaks in relation to wavelength. The first reflecting mirror 122 includes a ring resonator and a branch unit having two arms optically coupled to the ring resonator. The second reflecting mirror 124 is a distributed Bragg reflector (DBR) mirror including a sampled grating with a reflection spectrum having periodic peaks in relation to wavelength on a cycle different from that of first reflecting mirror 122. A laser resonator R is formed of the first reflecting mirror 122 and the second reflecting mirror 124. Reflection peaks of the first reflecting mirror 122 and second reflecting mirror 124 are, in a precise sense, periodic in relation to frequency of light, but is also approximately periodic in relation to wavelength, and they are thus referred to as having peaks periodically in relation to wavelength, in this specification. The gain unit 123 is arranged in the laser resonator R and generates optical gain by being supplied with driving power.

A first reflecting mirror heater 125 that is ring-shaped is provided on the ring resonator of the first reflecting mirror 122. The first reflecting mirror heater 125 heats the ring resonator of the first reflecting mirror 122 by being supplied with driving power from the control unit 20. The reflection spectrum of the first reflecting mirror 122 is controlled by this heating. A phase adjustment heater 126 is provided on one of the arms of the first reflecting mirror 122. The phase adjustment heater 126 heats the arm by being supplied with driving power from the control unit 20. Cavity length of the laser resonator R is adjusted by this heating. Wavelengths of longitudinal modes (resonator modes) of the laser resonator R are able to be controlled by this adjustment of the cavity length. A second reflecting mirror heater 127 is provided on the second reflecting mirror 124. The second reflecting mirror heater 127 heats the second reflecting mirror 124 by being supplied with driving power from the control unit 20. The reflection spectrum of the second reflecting mirror 124 is controlled by this heating.

The driving power supplied to each of the first reflecting mirror heater 125, the phase adjustment heater 126, and the second reflecting mirror heater 127 that are in the wavelength-tunable laser element 12 is adjusted. Laser oscillation is thereby caused at a wavelength where a reflection peak of the first reflecting mirror 122, a resonator mode of the laser resonator R, and a reflection peak of the second reflecting mirror 124 match one another, and a laser light beam L0 which is continuous wave (CW) light is output. That is, the first reflecting mirror heater 125, the phase adjustment heater 126, and the second reflecting mirror heater 127 form plural control elements that control the laser emission wavelength of the wavelength-tunable laser element 12, by being supplied with driving power.

The semiconductor optical amplifier 13 optically amplifies the laser light beam L0 and outputs a laser light beam L1 resulting from the optical amplification, by being supplied with driving power from the control unit 20.

The planar lightwave circuit 14 and the photodetector 15 form a wavelength monitor unit 17 for monitoring the laser emission wavelength (the wavelength of the laser light beam L0) of the wavelength-tunable laser element 12.

The planar lightwave circuit 14 is optically coupled to one of the arms of the first reflecting mirror 122 by a space coupling optical system (not illustrated in the drawings). A laser light beam L2 generated, similarly to the laser light beam L0, by laser emission in the wavelength-tunable laser element 12 is input from the arm to the planar lightwave circuit 14. The laser light beam L2 has a wavelength that is the same as the wavelength of the laser light beam L0. This planar lightwave circuit 14 includes an optical branching unit 141, an optical waveguide 142, an optical waveguide 143 having a ring resonator optical filter, and an optical waveguide 144 having a ring resonator optical filter.

The optical branching unit 141 branches the laser light beam L2 input to the optical branching unit 141 into three branches of laser light beams L3 to L5. The optical waveguide 142 then guides the laser light beam L3 to the photodetector 15. Furthermore, the optical waveguide 143 guides the laser light beam L4 to the photodetector 15. The optical waveguide 144 also guides the laser light beam L5 to the photodetector 15.

The ring resonator optical filters of the optical waveguides 143 and 144 have transmission spectra that are different from each other and that periodically change in relation to wavelength. As a result, the optical waveguides 143 and 144 respectively transmit the laser light beam L4 and the laser light beam L5 at transmissivity according to wavelength. In contrast, the laser light beam L3 reaches the photodetector 15 substantially without any loss dependent on wavelength because the laser light beam L3 is transmitted through the optical waveguide 142 having transmissivity that is substantially independent of wavelength.

The ring resonator optical filters of the optical waveguides 143 and 144 have transmission characteristics with the same cycle but phases different from each other in a range of ⅓ to ⅕ of one period.

The photodetector 15 includes photodiodes (PDs) 151, 152, and 153. The PD 151 serving as a second photodetector receives the laser light beam L3 transmitted through the optical waveguide 142 and outputs a second electric current signal corresponding to the received optical power. The PD 152 serving as a first photodetector receives the laser light beam L4 transmitted through the optical waveguide 143 and outputs a first electric current signal corresponding to the received optical power. The PD 153 serving as a first photodetector receives the laser light beam L5 transmitted through the optical waveguide 144 and outputs a first electric current signal corresponding to the received optical power. As described above, the photodetector 15 performs a first electric current signal output process and a second electric signal output process of outputting the first and second electric current signals as a monitoring result.

The temperature sensor 16 is formed of, for example, a thermistor. The temperature sensor 16 detects temperature of the wavelength-tunable laser element 12. The temperature sensor 16 outputs a detected signal including information on the detected temperature.

The Peltier element 11 has the wavelength-tunable laser element 12 mounted thereon and is able to adjust the temperature of the wavelength-tunable laser element 12.

The control unit 20 will be described next. The control unit 20 controls electric power to be supplied to the gain unit 123, the first reflecting mirror heater 125, the phase adjustment heater 126, the second reflecting mirror heater 127, the semiconductor optical amplifier 13, and the Peltier element 11.

The control unit 20 includes at least an arithmetic unit 21, a recording unit 22, an input unit 23, an output unit 24, and an electric power supplying unit 25. The arithmetic unit 21 includes, for example, a central processing unit (CPU) and performs various kinds of arithmetic processing for control. The recording unit 22 includes a recorder, such as a read only memory (ROM) where various programs and data, for example, to be used by the arithmetic unit 21 to perform arithmetic processing are stored. Furthermore, the recording unit 22 includes a recorder, such as a random access memory (RAM) used, for example: as a working space by the arithmetic unit 21 to perform arithmetic processing; and for recording results of the arithmetic processing by the arithmetic unit 21.

The input unit 23 receives input of, for example, an instruction signal from a higher-level device of the wavelength-tunable light source device 100, the two first electric current signals and the second electric current signal from the photodetector 15, and a detected signal from the temperature sensor. Information included in the received signals is recorded in the recording unit 22. The input unit 23 includes, for example, an analog-digital converter (ADC). The output unit 24 receives an instruction signal generated through arithmetic processing by the arithmetic unit 21, converts the instruction signal into an appropriate instruction signal, and outputs the appropriate instruction signal to the electric power supplying unit 25. The output unit 24 includes, for example, a digital-analog converter (DAC). The electric power supplying unit 25 supplies driving power on the basis of an instruction signal and includes, for example, a DC power source.

The control unit 20 is configured to be able to perform feedback control of the laser emission wavelength of the wavelength-tunable laser element 12. In this embodiment, the control unit 20 performs the following feedback control. The control unit 20 calculates a ratio (which may hereinafter be referred to as a PD ratio as appropriate) of one of the two first electric current signals from the photodetector 15 to the second electric current signal from the photodetector 15. On the basis of a correspondence relation between the PD ratio and the laser emission wavelength, the control unit 20 then detects a laser emission wavelength. This correspondence relation is found beforehand by, for example, experiments, and are recorded as table data in the recording unit 22. The control unit 20 controls the driving power to the phase adjustment heater 126 such that the PD ratio corresponds to a desired laser emission wavelength. The control unit 20 is thereby able to perform feedback control of the laser emission wavelength of the wavelength-tunable laser element 12. A ratio of a signal resulting from application of a correction coefficient to the second electric current signal to a signal resulting from application of a correction coefficient to one of the two first electric current signals from the photodetector 15 may be used as the PD ratio. Furthermore, a quantity corresponding to this ratio may be a ratio calculated using a signal resulting from application of a correction coefficient to one of the first electric current signal and the second electric current signal.

The correction coefficients for the first electric current signal and second electric current signal are obtained in advance by experiments, for example, are stored in the recording unit 22 in a format of, for example, table data or a relational expression, and are read and used by the control unit 20 as appropriate. The correction coefficients may be determined according to, for example, operation conditions of the wavelength-tunable light source device 100 and a temperature detected by the temperature sensor 16. Furthermore, the correction coefficients may be defined to be appropriate for being fitted to a standardized PD ratio curve (a wavelength discriminating curve). Application of correction coefficient to the first electric current signal and second electric current signal involves, for example, an arithmetic operation that is any of addition, subtraction, multiplication, and division.

### Tuning of Laser Emission Wavelength

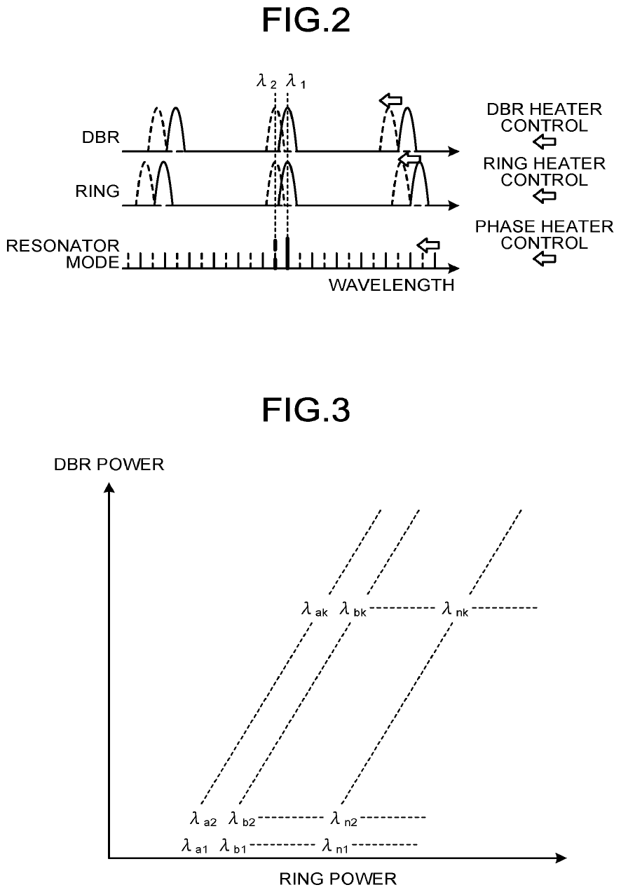

Tuning of the laser emission wavelength will be described next. FIG. 2 is a diagram for explanation of the tuning of the laser emission wavelength. In FIG. 2, the top is a reflection spectrum of the second reflecting mirror 124 (DBR), the middle is a reflection spectrum of the first reflecting mirror 122 (RING), and the bottom represents a spectrum of the resonator modes.

When the second reflecting mirror heater 127 (a DBR heater) is controlled by adjusting the driving power supplied, its reflecting spectrum is shifted on the wavelength axis from the form represented by the solid line to the form represented by the broken line, as indicated by the thick arrow in FIG. 2. Similarly, when the first reflecting mirror heater 125 (a RING heater) is controlled, its reflection spectrum is shifted on the wavelength axis from the form represented by the solid line to the form represented by the broken line in FIG. 2. Similarly, when the phase adjustment heater 126 (a Phase heater) is controlled, its spectrum is shifted on the wavelength axis from the form represented by the solid line to the form represented by the broken line in FIG. 2.

In the state represented by the solid lines, laser emission is occurring at a wavelength λ₁ where a reflection peak of the first reflecting mirror 122, a resonator mode of the laser resonator R, and a reflection peak of the second reflecting mirror 124 match one another in FIG. 2. To achieve this state, a setting process of respectively setting, on the basis of electric power that is supplied, wavelength positions at which the DBR and RING reflection spectra peak, is performed at the DBR heater and the RING heater. Furthermore, in this setting process, the Phase heater sets, on the basis of electric power that is supplied, a wavelength position at which the resonator modes peak. When the state represented by the broken lines is achieved by controlling the heaters, a reflection peak of the first reflecting mirror 122, a resonator mode of the laser resonator R, and a reflection peak of the second reflecting mirror 124 match one another at a wavelength λ₂, and the laser emission wavelength is thus able to be tuned to the wavelength λ₂. By finely adjusting the driving power in controlling the heaters, the laser emission wavelength is able to be finely tuned, with the match among the resonator mode and the two reflection peaks maintained. The driving power to each heater is able to be controlled by the electric current that is supplied.

An example of relations between the laser emission wavelength and the driving power to each heater will be described next. FIG. 3 is a diagram illustrating an example of relations between DBR power, RING power, and the laser emission wavelengths. The DBR power is electric power supplied to the DBR heater. The RING power is electric power supplied to the RING heater. In FIG. 5, λa1, λa2, . . . , λak, . . . ; λb1, λb2, . . . , λbk, . . . ; and λn1, λn2, . . . , λnk, . . . represent laser emission wavelengths obtained by specific combinations of RING power and DBR power. These wavelengths are wavelengths different from one another. Furthermore, for example, λa1, λa2, . . . , λak, . . . are wavelengths that are adjacent to each other. Wavelengths being adjacent means that a wavelength difference between λAB (A=a, b, c, . . . , n; and B=1, 2, 3, . . . , k) and λA(B±1) is smaller than a wavelength difference between λAB and λA′B (A′≠A). Similarly, λb1, λb2, . . . , λbk, . . . are also wavelengths adjacent to each other, and λn1, λn2, . . . , λnk, . . . are also wavelengths adjacent to each other. Therefore, the laser emission wavelength may be changed continuously in FTF, for example, as described below. Specifically, the combination of RING power and DBR power may be changed along a slanted broken line joining λa1, λa2, . . . , λak, . . . , and the electric current for the Phase heater may be changed correspondingly to this change.

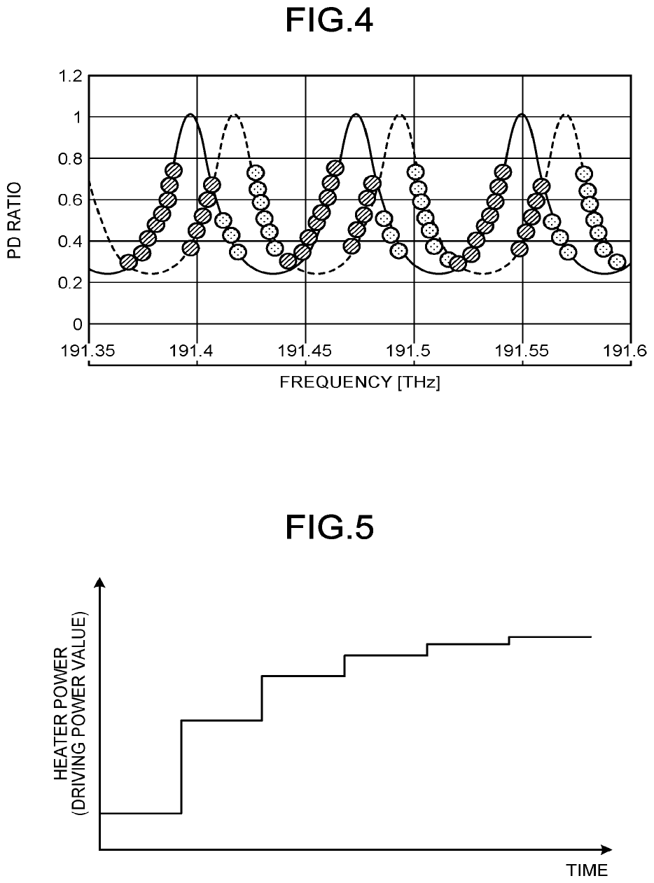

A case where wavelength monitoring is performed using two ring resonator filters like in this embodiment will be described next by reference to FIG. 4. FIG. 4 illustrates PD ratio characteristics. The horizontal axis in FIG. 4 represents wavelength of light in frequency.

The solid line in FIG. 4 represents the PD ratio of the first electric current signal output by the PD 152 to the second electric current signal, the PD ratio indicating characteristics due to the ring resonator optical filter of the optical waveguide 143. Furthermore, the broken line in FIG. 4 represents the PD ratio of the first electric current signal output by the PD 153 to the second electric current signal, the PD ratio indicating characteristics due to the ring resonator optical filter of the optical waveguide 144. One of these two PD ratio curves (also called wavelength discriminating curves) is higher in its wavelength monitoring accuracy, the one being the PD ratio curve that changes more largely, that is, is larger in gradient of the curve, in relation to change in the laser emission wavelength, than the other one. Therefore, which one of the wavelength discriminating curves is to be used is preferably selected according to the laser emission wavelength. The circles illustrated in FIG. 4 specifically represent control points (locked points) of wavelength (frequency) and the locked points are set on the curves where the gradient are larger correspondingly to the wavelength (frequency).

When feedback control is used by using such wavelength discriminating curves in tuning the wavelength from the current laser emission wavelength to a target wavelength, performing feedback control to the target wavelength at once may instantaneously or unstably change the laser emission wavelength. Furthermore, when the emission wavelength of a wavelength-tunable laser element is controlled using Vernier control like in this embodiment, or when a wavelength discriminating curve to be used is changed midway through tuning of the wavelength from the current laser emission wavelength to the target wavelength, the laser emission wavelength may be changed unstably. In addition, when control is performed such that the laser emission wavelength is finely changed by FTF, a laser light beam may be emitted in such a state where the laser emission wavelength is changed unstably.

In this embodiment, the control unit 20 has recorded wavelength corresponding control set values corresponding to intermediate wavelengths discretely provided between the current laser emission wavelength and a target wavelength. When a command to change the laser emission wavelength to a target wavelength is received, a control process of controlling the heaters is performed by sequentially setting the wavelength corresponding control set values corresponding to these intermediate wavelengths as control targets. In this control process, control for monotonously changing the laser emission wavelength is performed, for example. Discrete intermediate wavelengths are thus set between the current laser emission wavelength and a target wavelength and wavelength corresponding control set values corresponding to these intermediate wavelengths are sequentially set as control targets. The laser emission wavelength is thereby able to be changed monotonously and stably in tuning of the laser emission wavelength.

### First Control Example

Various examples of control by the control unit 20 will be described below. In the following examples, the control is performed in a state where driving power is being supplied to the gain unit 123 and the semiconductor optical amplifier 13. Firstly, in a first control example, wavelength corresponding control set values are driving power set values (driving power values) supplied respectively to the DBR heater, the RING heater, and the Phase heater, the driving power set values having been set correspondingly to discrete intermediate wavelengths between the current laser emission wavelength and a target wavelength.

FIG. 5 is a diagram illustrating an example of control of the driving power (the heater power) supplied to one of the heaters in the first control example. In FIG. 5, the horizontal axis represents time from reception of a command to change the laser emission wavelength to the target wavelength. In the example illustrated in FIG. 5, the heater power is changed stepwise in relation to time. The heater power at each step is the driving power set for laser emission at an intermediate wavelength. Changing the heater power stepwise in this way is able to be implemented by, for example, changing the value of driving power supplied to each heater stepwise in relation to time. Relations between the heater power and the laser emission wavelength for the heaters are like the relation illustrated in FIG. 5, have been recorded in the recording unit 22 as the table data, and are read and used for arithmetic operations by the arithmetic unit 21 as appropriate. FIG. 5 is an example for a certain heater, and the forms of steps, such as the step widths (increments), for the heaters may be different from one another. Specifically, electric power for each heater is set to change the laser emission wavelength with the match among the resonator mode and the two reflection peaks maintained.

Each heater may have equal step widths for the electric power but as illustrated in FIG. 5, preferably, the first step width is made large and the later step widths are thereafter made smaller. This is preferable for monotonous change because time for completion of the change to the target wavelength is thereby able to be shortened and the laser emission wavelength is able to be prevented from exceeding the target wavelength. The step width needs to be set small near the target wavelength so that the target wavelength is not exceeded. However, when the difference between the target wavelength and the current wavelength is large, there is no need to be concerned about the target wavelength being exceeded even if the step width is large. Therefore, making the step width small toward the target wavelength leads to time saving.

Hereinafter, some control flows according to the present disclosure will be described as examples below. In these control flows, the driving power for the DBR heater, RING heater, and Phase heater, the driving power being needed for output of a target wavelength, is assumed to be larger than the driving power for the DBR heater, RING heater, and Phase heater before start of the control flows.

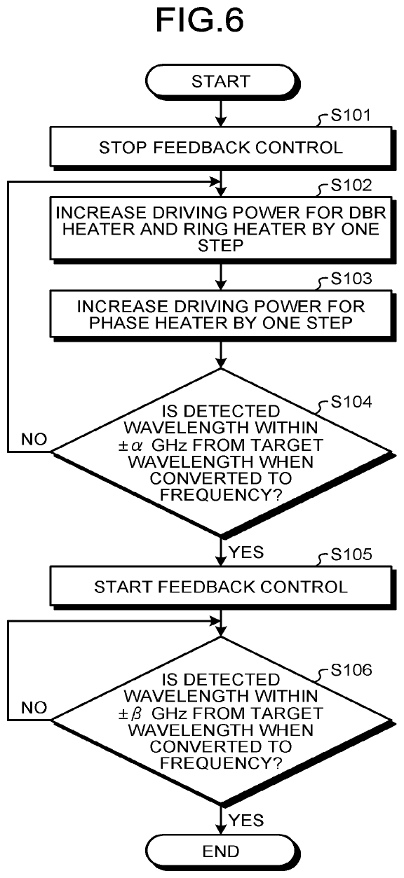

FIG. 6 is a diagram illustrating a control flow of the first control example. This control flow starts when an instruction signal to change the laser emission wavelength to a predetermined wavelength (a target wavelength) is received in a state where the control unit 20 is performing feedback control.

The control unit 20 stops the feedback control at Step S101. Subsequently, at Step S102, the control unit 20 increases the driving power for the DBR heater and RING heater by one step. More specifically, the driving power values for the DBR heater and RING heater are increased by one step illustrated in FIG. 5. The DBR power and RING power corresponding to the target values are supplied to the DBR heater and RING heater. After the supply is started, elapse of a predetermined time period is waited at each step. The driving power values at the steps in FIG. 5 are respectively values corresponding intermediate wavelengths. One reflection peak of the first reflecting mirror 122 and one reflection peak of the second reflecting mirror 124 move from the laser emission wavelength before the start of control to an intermediate wavelength nearest to that laser emission wavelength. Subsequently, at Step S103, the control unit 20 increases the driving power for the Phase heater by one step. More specifically, the driving power value for the Phase heater is increased by one step illustrated in FIG. 5. Phase power corresponding to the target value is supplied to the Phase heater. After the supply is started, elapse of a predetermined time period is waited at each step. The driving power values at the steps in FIG. 5 are respectively values corresponding to intermediate wavelengths. One of the peaks of the resonator modes thereby moves from that laser emission wavelength before the start of control to an intermediate wavelength nearest to that laser emission wavelength. Step S102 and Step S103 may be executed simultaneously, or Step S103 may be executed before Step S102.

Subsequently, at Step S104, the control unit 20 detects a wavelength on the basis of the PD ratio, and determines whether the wavelength detected is within a predetermined range (within ±α GHz from the target wavelength, where α is a predetermined constant, for example, 1, by conversion into frequencies). If not within the predetermined range (Step S104, No), the control is returned to Step S102, and Steps 5102 to 5104 are repeated. One reflection peak of the first reflecting mirror 122, one reflection peak of the second reflecting mirror 124, and one peak of the resonator modes are thereby sequentially moved to an adjacent intermediate wavelength. On the contrary, if within the predetermined range (Step S104, Yes), the control is advanced to Step S105.

Subsequently, at Step S105, the control unit 20 starts feedback control. At Step S106, the control unit 20 then determines whether the wavelength detected on the basis of the PD ratio is within a predetermined range (within ±β GHz from the target wavelength, where β is a predetermined constant, for example, 0.5, smaller than α, by conversion into frequencies) from the target wavelength. If not within the predetermined range (Step S106, No), Step S106 is repeated in the control. If within the predetermined range (Step S106, Yes), it is determined that the wavelength has converged and execution of the flowchart is ended. The predetermined constant β may be a predetermined constant larger than α, instead.

The predetermined range, ±α GHz, is preferably set to a range over which the laser emission wavelength is able to be changed monotonously and stably even if feedback control is started.

### Second Control Example

A second control example will be described next. In the second control example, similarly to the first control example, the wavelength corresponding control set values are driving power values supplied respectively to the DBR heater, the RING heater, and the Phase heater, the driving power values having been set correspondingly to discrete intermediate wavelengths between the current laser emission wavelength and a target wavelength. In this control flow, the driving power for the DBR heater, RING heater, and Phase heater, the driving power being needed for output of the target wavelength, is assumed to be larger than the driving power for the DBR heater, RING heater, and Phase heater before start of the control flow.

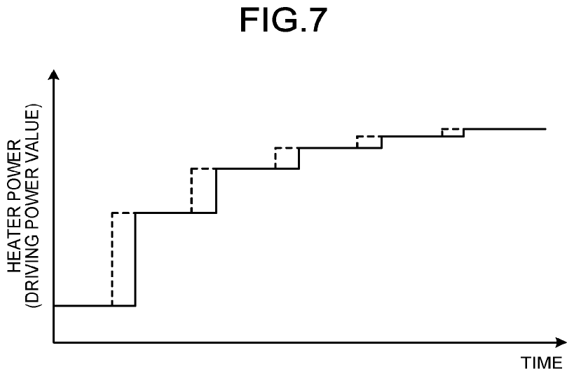

FIG. 7 is a diagram illustrating an example of control of heater power supplied to two of the heaters in the second control example. In FIG. 7, the horizontal axis represents time from reception of a command to change the laser emission wavelength to a target wavelength. Furthermore, the solid line and broken line in FIG. 7 represent heater power respectively for different heaters. In the example illustrated in FIG. 7, the heater power is changed stepwise in relation to time, similarly to FIG. 5. However, the heater to which the heater power represented by the broken line is supplied is a heater corresponding to an element (the first reflecting mirror 122, the second reflecting mirror 124, or the cavity length of the laser resonator R) having longer response time in relation to electric power than the heater to which the heater power represented by the solid line is supplied. For an element having long response time, the delay in response is thus able to be compensated by changing the heater power early.

The second control example may be executed by a control flow similar to that of the first control example.

### Third Control Example

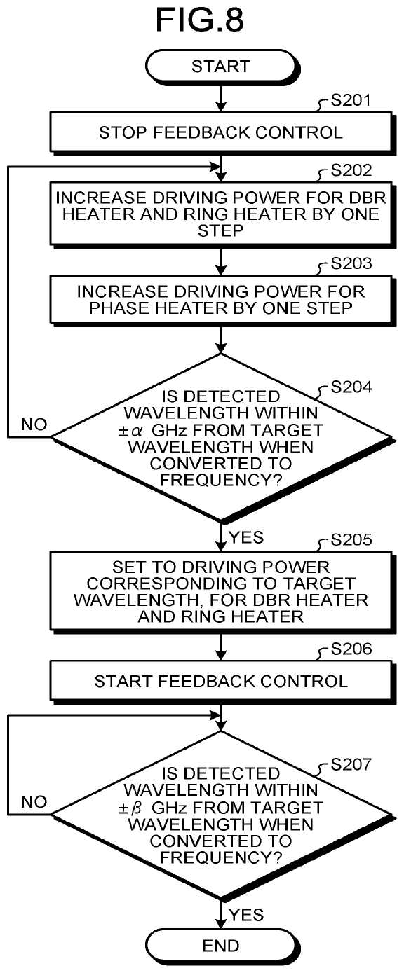

FIG. 8 is a diagram illustrating a control flow of a third control example. This control flow starts when an instruction signal to change the laser emission wavelength to a target wavelength is received in a state where the control unit 20 is performing feedback control. In this control flow, the driving power for the DBR heater, RING heater, and Phase heater, the driving power being needed for output of the target wavelength, is assumed to be larger than the driving power for the DBR heater, RING heater, and Phase heater before start of the control flow.

Steps S201 to S204 are the same as Steps S101 to S104 in the first control example. That is, the control unit 20 stops the feedback control at Step S201. Subsequently, at Step S202, the control unit 20 increases the driving power for the DBR heater and RING heater by one step. More specifically, the values of the driving power for the DBR heater and RING heater are increased by one step illustrated in FIG. 5. The DBR power and RING power corresponding to the target values are supplied to the DBR heater and RING heater. After the supply is started, elapse of a predetermined time period is waited at each step. The value of driving power at each step in FIG. 5 is a value corresponding to an intermediate wavelength. Subsequently, at Step S203, the control unit 20 increases the driving power for the Phase heater by one step. More specifically, the value of the driving power for the Phase heater is increased by one step illustrated in FIG. 5. Phase power corresponding to the target value is supplied to the Phase heater. After the supply is started, elapse of a predetermined time period is waited at each step. The value of driving power at each step in FIG. 5 is a value corresponding to an intermediate wavelength. Step S202 and Step S203 may be executed simultaneously, or Step S203 may be executed before Step S202.

Subsequently, at Step S204, the control unit 20 determines whether the wavelength detected on the basis of the PD ratio is within a predetermined range (within ±α GHz from the target wavelength by conversion to frequencies) from the target wavelength. This α is a predetermined constant and is a value larger than that of α in the first control example. If not within the predetermined range (Step S204, No), the control is returned to Step S202. If within the predetermined range (Step S204, Yes), the control is advanced to Step S205.

Subsequently, at Step S205, the control unit 20 sets the driving power for the DBR heater and RING heater, the driving power corresponding to the target wavelength, and supplies the set electric power to the heaters, respectively.

Subsequently, at Step S206, the control unit 20 starts feedback control. At Step S207, the control unit 20 then determines whether the wavelength detected on the basis of the PD ratio is within a predetermined range (within ±β GHz, where β is a predetermined constant smaller than α, in frequency) from the target wavelength. If not within the predetermined range (Step S207, No), Step S207 is repeated in the control. If within the predetermined range (Step S207, Yes), it is determined that the wavelength has converged and execution of the flowchart is ended. This β may be a predetermined constant larger than α, instead.

As compared to the first control example, the third control example has an additional step of setting the driving power for the DBR heater and RING heater, the driving power corresponding to the target wavelength, and supplying the set electric power respectively to the heaters at Step S205. In the first control example, if α is comparatively large and the control from the start to the end is repeatedly executed, error may be accumulated in the set driving power for the heaters, in particular, in the driving power for the DBR heater and RING heater. Therefore, in this third control example, when a detected wavelength is in a predetermined range from the target wavelength, the control unit 20 sets the driving power for the DBR heater and RING heater, the driving power corresponding to the target wavelength. The problem of error being accumulated is thereby able to be solved. The driving power for the DBR heater and RING heater, which corresponds to the target wavelength, may be set by referring to the table data recorded in the recording unit 22. Furthermore, on the basis of a difference between a detected wavelength and the target wavelength, an amount of increase in the driving power needed to change the laser emission wavelength by that difference may be calculated and the driving power may be set by adding that amount of increase to the current driving power value. In this third control example, the driving power for the DBR heater and RING heater is set to the driving power corresponding to the target wavelength, but this setting may be executed for one of the heaters instead. In this case, control like that in the first control example may be executed for the other heater.

### Fourth Control Example

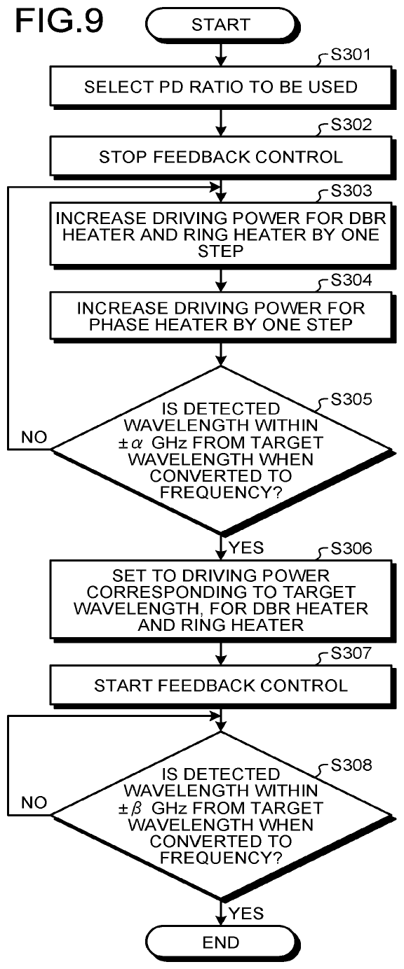

FIG. 9 is a diagram illustrating a control flow of a fourth control example. This control flow starts when an instruction signal to change the laser emission wavelength to a target wavelength is received in a state where the control unit 20 is performing feedback control. In this control flow, the driving power for the DBR heater, RING heater, and Phase heater, the driving power being needed for output of the target wavelength, is assumed to be larger than the driving power for the DBR heater, RING heater, and Phase heater before start of the control flow.

At Step S301, the control unit 20 selects, as a PD ratio to be used in detection of a wavelength, a PD ratio based on one of two wavelength discriminating curves. Specifically, the control unit 20 selects, from the two PD ratios, the PD ratio of the one that changes more largely in relation to change in the laser emission wavelength at the target wavelength.

Steps S302 to S308 are the same as Steps S201 to S207 in the third control example. That is, the control unit 20 stops the feedback control at Step S302. Subsequently, at Step S303, the control unit 20 increases the driving power for the DBR heater and RING heater by one step. More specifically, the values of the driving power for the DBR heater and RING heater are increased by one step illustrated in FIG. 5. The DBR power and RING power corresponding to the target values are supplied to the DBR heater and RING heater. After the supply is started, elapse of a predetermined time period is waited at each step. The value of driving power at each step in FIG. 5 is a value corresponding to an intermediate wavelength. Subsequently, at Step S304, the control unit 20 increases the driving power for the Phase heater by one step. More specifically, the value of the driving power for the Phase heater is increased by one step illustrated in FIG. 5. Phase power corresponding to the target value is supplied to the Phase heater. After the supply is started, elapse of a predetermined time period is waited at each step. The value of driving power at each step in FIG. 5 is a value corresponding to an intermediate wavelength. Step S303 and Step S304 may be executed simultaneously, or Step S303 may be executed before Step S304.

Subsequently, at Step S305, the control unit 20 determines whether the wavelength detected on the basis of the PD ratio is within a predetermined range (within ±α GHz from the target wavelength by conversion to frequencies) from the target wavelength. This α is a predetermined constant and is a value larger than that of α in the first control example. If not within the predetermined range (Step S305, No), the control is returned to Step S303. If within the predetermined range (Step S305, Yes), the control is advanced to Step S306.

Subsequently, at Step S306, the control unit 20 sets the driving power for the DBR heater and RING heater, which corresponds to the target wavelength, and supplies the set electric power to the heaters, respectively.

Subsequently, at Step S307, the control unit 20 starts feedback control. At Step S308, the control unit 20 then determines whether the wavelength detected on the basis of the PD ratio is within a predetermined range (within ±β GHz from the target wavelength, where β is a predetermined constant smaller than α, by conversion to frequencies) from the target wavelength. If not within the predetermined range (Step S308, No), Step S308 is repeated in the control. If within the predetermined range (Step S308, Yes), it is determined that the wavelength has converged and execution of the flowchart is ended. This β may be a predetermined constant larger than α, instead.

In this fourth control example, the wavelength detecting process of detecting a wavelength is performed by selecting one of two PD ratios, the one being larger in change in relation to change in the laser emission wavelength at the target wavelength, and the PD ratio to be used is thus not changed midway through the control. As a result, the control processing by the control unit 20 is facilitated. Furthermore, the accuracy of wavelength detection near the target wavelength is able to be improved.

### Fifth Control Example

A fifth control example is applicable to the first to fourth control examples described above and a sixth control example described later. In this fifth control example, when the laser emission wavelength is monotonously changed, electric power supplied to the DBR heater and RING heater is controlled such that a shift between a reflection peak of the first reflecting mirror 122 and a reflection peak of the second reflecting mirror 124 becomes equal to or less than the half width at half maximum of one of these reflection peaks, the one having the narrower half width at half maximum, and the laser emission wavelength is discretely changed by steps each equal to or less than the narrower one of the half widths at half maximum of the reflection peaks.

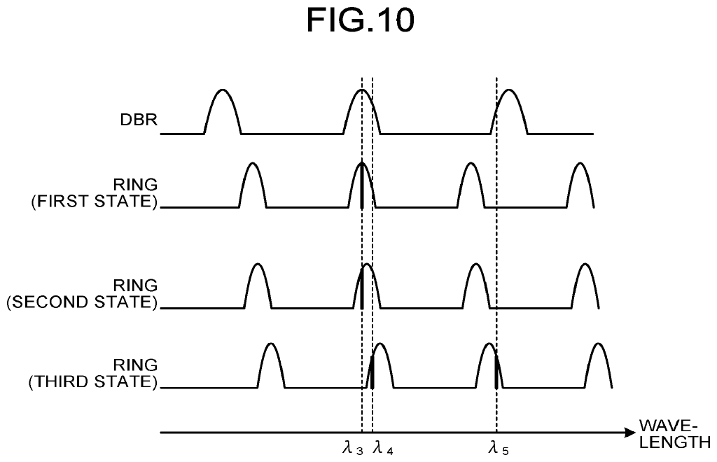

FIG. 10 is a diagram for explanation of control of wavelength in the fifth control example. Firstly, the current reflection spectrum of the second reflecting mirror 124 (DBR) is assumed to be in the top state and the current reflection spectrum of the first reflecting mirror 122 (RING) is assumed to be in a first state, in FIG. 10. The laser emission wavelength at that time is λ₃. The half width at half maximum of a reflection peak of the second reflecting mirror 124 is narrower than the half width at half maximum of a reflection peak of the first reflecting mirror 122.

In a case where the RING reflection spectrum is shifted like in a second state in FIG. 10, the laser emission wavelength almost does not change from λ₃ and the single mode oscillation state is maintained. However, in a case where the RING reflection spectrum is largely shifted as illustrated in the third state in FIG. 10, the similar overlaps between the reflections peak of the DBR reflection spectrum and the reflection peak of the RING reflection spectrum are generated at the wavelength λ4 and the wavelength λ5. This may unfavorably lead to a multi-mode oscillation state where laser is emitted at these two wavelengths.

Therefore, electric power supplied to the DBR heater and RING heater are preferably controlled such that the shift between the reflection peak of the first reflecting mirror 122 and the reflection peak of the second reflecting mirror 124 becomes small. In particular, control is performed such that the shift becomes equal to or less than the half width at half maximum of one of the reflection peak of the first reflecting mirror 122 and the reflection peak of the second reflecting mirror 124, the one having the narrower half width at half maximum. Multi-mode oscillation is thereby able to be prevented, the overlap between the reflection peaks of the spectra is thereby able to be maintained large to some extent, and the optical power of the laser light beam emitted is thus able to be prevented from being reduced.

Furthermore, the difference between two adjacent wavelength corresponding control set values may be controlled to be equal to or less than the half width at half maximum of one of the reflection peak of the first reflecting mirror 122 and the reflection peak of the second reflecting mirror 124, the one having the narrower half width at half maximum. In addition, this difference is preferably controlled to be equal to or less than the half width at half maximum of a spectrum of a combined reflection peak formed of one of plural reflection peaks of the first reflecting mirror 122 and one of plural reflection peaks of the second reflecting mirror 124, these two reflection peaks overlapping each other at the same wavelength. What is more, the difference between the two adjacent wavelength corresponding control set values is preferably controlled to be equal to or less than the half width at half maximum of the oscillation spectrum of the laser light beam L1 in a state where laser emission is occurring with one of the plural reflection peaks of the first reflecting mirror 122, one of the plural reflection peaks of the second reflecting mirror 124, and one of the resonator modes overlap one another at the same wavelength. Specifically, for example, the interval between the intermediate wavelengths, the interval having been converted to a frequency, is preferably 1 GHz or lower and more preferably 0.5 GHz or lower. The same applies to the step by which the shift or the laser emission wavelength is discretely changed, the shift being between a reflection peak of the first reflecting mirror 122 and a reflection peak of the second reflecting mirror 124.

### Sixth Control Example

In the first to fifth control examples, the wavelength corresponding control set values are driving power values supplied respectively to the DBR heater, the RING heater, and the Phase heater, the driving power values having been set correspondingly to discrete intermediate wavelengths between the current laser emission wavelength and a target wavelength. However, in a sixth control example described below, a wavelength corresponding control set value is a ratio of one of two first electric current signals to a second electric current signal, that is, one of two PD ratios, the ratio having been set correspondingly to an intermediate wavelength.

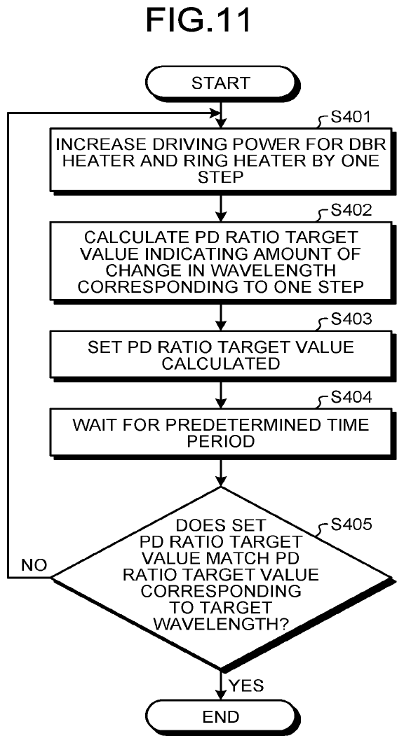

FIG. 11 is a diagram illustrating a control flow of the sixth control example. This control flow starts when an instruction signal to change the laser emission wavelength to a predetermined wavelength (a target wavelength) is received in a state where the control unit 20 is performing feedback control.

Firstly, at Step S401, the control unit 20 increases the driving power for the DBR heater and RING heater by one step. More specifically, the values of the driving power for the DBR heater and RING heater are increased by one step illustrated in FIG. 5. The DBR power and RING power corresponding to the target values are supplied to the DBR heater and RING heater. One reflection peak of the first reflecting mirror 122 and one reflection peak of the second reflecting mirror 124 thereby move from the laser emission wavelength before the start of control to an intermediate wavelength nearest to that laser emission wavelength.

Subsequently, at Step S402, the control unit 20 calculates a PD ratio target value indicating an amount of change in wavelength corresponding to an amount of increase in driving power corresponding to the one step increased at Step S401. This PD ratio target value is a value of PD ratio corresponding to an intermediate wavelength nearest to the laser emission wavelength before the start of the control.

Subsequently, at Step S403, the control unit 20 sets the PD ratio target value calculated at Step S403. Feedback control for controlling the driving power to the phase adjustment heater 126 is thereby executed to achieve the PD ratio target value. Through this feedback control, one reflection peak of the first reflecting mirror 122, one reflection peak of the second reflecting mirror 124, and a resonator mode match one another at the intermediate wavelength nearest to the laser emission wavelength before the start of the control.

Subsequently, at Step S404, the control unit 20 executes processing of waiting for a predetermined wait time until the feedback control is stabilized. This wait time is preferably set according to the response speed of each heater, for example, but may be set to zero.

Subsequently, at Step S405, the control unit 20 determines whether the set PD ratio target value matches the PD ratio target value corresponding to the target wavelength. If not matching (Step S405, No), the control is returned to Step S401 and the processing at Steps S401 to S405 is repeated. If matching (Step S405, Yes), it is determined that the wavelength has converged and execution of the flowchart is ended.

In this sixth example, while feedback control is being continued, the driving power for the DBR heater and RING heater is changed stepwise and the PD ratio target value is calculated and set according to the change. The laser emission wavelength is thereby able to be changed stably even if there are disturbances, such as changes in the environmental temperature.

The target wavelength may be longer or shorter than the current laser emission wavelength. Therefore, the amount of increase or decrease in the driving power supplied to each heater may be changed as appropriate according to the relation between the target wavelength and the current laser emission wavelength and the relation between the increase or decrease in the driving power and the moving direction of the reflection peak on the wavelength axis, the movement resulting from the increase or decrease in the driving power.

The present disclosure is not limited by the above described embodiments. The present disclosure also includes those formed by combination of any of the above described components of the embodiments as appropriate. For example, in the first to fourth and sixth control examples, the difference between the wavelength before the start of control and the intermediate wavelength for the first step, the wavelength difference corresponding to the one step of intermediate wavelength, and the difference between the last intermediate wavelength and the target wavelength are each preferably equal to or less than the half width at half maximum described as an example in the fifth control example. Multi-mode oscillation is thereby able to be prevented from occurring midway through changing of the wavelength, the overlap between the reflection peaks of the spectra is thereby able to be maintained large to some extent, and the optical power of the laser light beam emitted is thus able to be prevented from being reduced. Therefore, FTF is able to be implemented favorably. Furthermore, further effects and modifications can be easily derived by those skilled in the art. Therefore, wider aspects of the present disclosure are not limited to the above described embodiments, and various modifications can be made.

The present disclosure can also be appropriately applied to a wavelength-tunable laser device for communication use.

According to an embodiment, it is possible to obtain an effect of enabling laser emission wavelength to be changed monotonously and stably when the laser emission wavelength is tuned.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A wavelength-tunable light source device, comprising:
a wavelength-tunable laser element including:
a laser resonator having two reflecting mirrors having respective periodic peaks of reflection spectrums with respect to wavelength, cycles of the periodic peaks being different from each other;
a gain unit arranged in the laser resonator; and
a plurality of control elements that control respective laser emission wavelengths in response to electric power supplied to the control elements; and
a control unit, including an arithmetic unit and a recording unit, that controls the electric power supplied to the control elements, wherein
the control elements set, on a basis of the electric power, respective at least wavelength positions where the reflection spectrums of the two reflecting mirrors peak, and
the control unit controls the control elements by setting, as sequential control targets, wavelength corresponding control set values, which correspond to discrete intermediate wavelengths between a current laser emission wavelength and a target wavelength.

2. The wavelength-tunable light source device according to claim 1, wherein the control unit increase and decrease the electric power to be supplied to the control elements in a stepwise manner with respect to time.

3. The wavelength-tunable light source device according to claim 2, wherein the control unit performs changes on the electric power to be supplies to the control elements in a manner that the changes of the electric power are different from each other.

4. The wavelength-tunable light source device according to claim 1, wherein the wavelength corresponding control set values are values of driving powers supplied to the control elements, the values being set to correspond to the intermediate wavelengths.

5. The wavelength-tunable light source device according to claim 4, further comprising:
a wavelength monitor unit for monitoring the laser emission wavelengths of the wavelength-tunable laser element, wherein
the control unit, after controlling the control elements such that the wavelength corresponding control set values are the control targets,
detects the laser emission wavelengths on a basis of a monitoring result by the wavelength monitor unit, and
sets, as a driving power value corresponding to the target wavelength, a driving power value supplied to at least one of the control elements in a case where the control unit determines that the laser emission wavelengths are within a predetermined range from the target wavelength.

6. The wavelength-tunable light source device according to claim 4, further comprising:
a wavelength monitor unit for monitoring the laser emission wavelengths of the wavelength-tunable laser element, wherein
the control unit, after controlling the control elements such that the wavelength corresponding control set values are the control targets, detects the laser emission wavelengths on a basis of a monitoring result by the wavelength monitor unit, and sets, on a basis of a difference between the detected laser emission wavelengths and the target wavelength, a driving power value supplied to at least one of the control elements in a case where the control unit determines that the laser emission wavelengths are within a predetermined range from the target wavelength.

7. The wavelength-tunable light source device according to claim 5, wherein
the wavelength monitor unit includes:
two optical filters having respective transmission spectrums different from each other and change periodically with respect to wavelengths;
two first photodetectors that receive respective laser light beams and output first electric current signals, the laser light beams being output from the wavelength-tunable laser element and thereafter transmitted through the two optical filters; and
a second photodetector that receives a laser light beam and outputs a second electric current signal, the laser light beam being received without substantially any loss dependent on wavelength after being output from the wavelength-tunable laser element, and
the control unit detects a wavelength of the laser light beam on a basis of one of ratios of the two first electric current signals to the second electric current signal, the one being larger in change in relation to change in the laser emission wavelength at the target wavelength.

8. The wavelength-tunable light source device according to claim 1, further comprising:
a wavelength monitor unit for monitoring the laser emission wavelengths of the wavelength-tunable laser element, wherein
the wavelength monitor unit includes:
two optical filters having transmission spectrums different from each other and change periodically with respect to wavelength;
two first photodetectors that receive respective laser light beams and output first electric current signals, the laser light beams being output from the wavelength-tunable laser element and thereafter transmitted through the two optical filters; and
a second photodetector that receives a laser light beam and outputs a second electric current signal, the laser light beam being received without substantially any loss dependent on wavelength after being output from the wavelength-tunable laser element,
the control unit detects a wavelength of the laser light beam on a basis of a ratio of one of the two first electric current signals to the second electric current signal, and
the wavelength corresponding control set values are each a ratio of one of the two first electric current signals to the second electric current signal, the ratio being set correspondingly to the intermediate wavelengths.

9. The wavelength-tunable light source device according to claim 8, wherein the control unit detects a wavelength of the laser light beam on a basis of one of ratios of the two first electric current signals to the second electric current signal, the one being larger in change in relation to change in the laser emission wavelength at the target wavelength.

10. The wavelength-tunable light source device according to claim 1, wherein the wavelength-tunable light source device is configured such that a difference between two adjacent ones of the wavelength corresponding control set values is equal to or less than a half width at half maximum of a spectrum of a combined reflection peak formed of a reflection peak of one of the two reflecting mirrors and a reflection peak of the other one of the two reflecting mirrors, the reflection peaks overlapping each other at the same wavelength.

11. The wavelength-tunable light source device according to claim 10, wherein the wavelength-tunable light source device is configured such that the difference between the two adjacent wavelength corresponding control set values is equal to or less than a half width at half maximum of an oscillation spectrum of laser light beam output in a state where the spectrum of the combined reflection peak and a resonator mode of the laser resonator match each other.

12. A wavelength-tunable light source device, comprising:
a wavelength-tunable laser element including:
a laser resonator formed of two reflecting mirrors having reflection spectra with periodic peaks on cycles different from each other in relation to wavelength;
a gain unit arranged in the laser resonator; and
plural control elements that control laser emission wavelength by being supplied with electric power; and
a control unit that comprises an arithmetic unit and a recording unit and controls the electric power supplied to the plural control elements, wherein
the control unit controls the plural control elements to monotonously change the laser emission wavelength from a current laser emission wavelength to a target wavelength and when monotonously changing the laser emission wavelength, controls the electric power such that a shift between reflection peaks of the two reflecting mirrors is equal to or less than a half width at half maximum of a narrower one of half widths at half maximum of the reflection peaks of the two reflecting mirrors.

13. The wavelength-tunable light source device according to claim 12, wherein the wavelength-tunable light source device is configured such that the shift is equal to or less than a half width at half maximum of a spectrum of a combined reflection peak formed of a reflection peak of one of the two reflecting mirrors and a reflection peak of the other one of the two reflecting mirrors, the reflection peaks overlapping each other at the same wavelength.

14. The wavelength-tunable light source device according to claim 13, wherein the wavelength-tunable light source device is configured such that the shift is equal to or less than a half width at half maximum of an oscillation spectrum of laser light beam output in a state where the combined reflection peak and a resonator mode of the laser resonator match each other.

15. A control method for a wavelength-tunable laser element and executed by a control unit including an arithmetic unit and a recording unit, the wavelength-tunable laser element including: a laser resonator formed of two reflecting mirrors having reflection spectra with periodic peaks on cycles different from each other in relation to wavelength; a gain unit arranged in the laser resonator; and plural control elements that control laser emission wavelength by being supplied with electric power, the control method comprising:
a setting process of respectively setting, at the plural control elements, on a basis of the electric power supplied, wavelength positions where the reflection spectra of at least two reflecting mirrors peaks; and
a control process of controlling the plural control elements by sequentially setting control targets that are wavelength corresponding control set values corresponding to discrete intermediate wavelengths between a current laser emission wavelength and a target wavelength.

16. The control method for the wavelength-tunable laser element, according to claim 15, wherein the control process includes changing amounts of increase or decrease in the electric power supplied to the plural control elements stepwise in relation to time.

17. The control method for the wavelength-tunable laser element, according to claim 15, wherein the control process includes supplying electric power to the plural control elements such that the amounts of increase or decrease differ from one another.

18. The control method for the wavelength-tunable laser element, according to claim 15, wherein the wavelength corresponding control set values are values of driving power supplied respectively to the plural control elements, the values being set correspondingly to the intermediate wavelengths.

19. The control method for the wavelength-tunable laser element, according to claim 18, further comprising:
a wavelength detecting process of detecting the laser emission wavelength after controlling the plural control elements such that the wavelength corresponding control set values that are the control targets are achieved, wherein
the control process includes setting a value of driving power supplied to at least one of the plural control elements to a value of driving power corresponding to the target wavelength in a case where the laser emission wavelength has been determined to be in a predetermined range from the target wavelength.

20. The control method for the wavelength-tunable laser element, according to claim 18, further comprising:
a wavelength detecting process of detecting the laser emission wavelength after controlling the plural control elements such that the wavelength corresponding control set values that are the control targets are achieved, wherein
the control process includes setting a value of driving power supplied to at least one of the plural control elements, on a basis of a difference between the laser emission wavelength detected and the target wavelength, in a case where the laser emission wavelength has been determined to be in a predetermined range from the target wavelength.

21. The control method for the wavelength-tunable laser element, according to claim 19, further comprising:
a first electric current signal outputting process of receiving a laser light beam and outputting two first electric current signals, the laser light beam being output from the wavelength-tunable laser element and thereafter transmitted two optical filters having transmission spectra that are different from each other and that change periodically in relation to wavelength; and
a second electric current signal outputting process of receiving a laser light beam and outputting a second electric current signal, the laser light beam being output from the wavelength-tunable laser element and thereafter not transmitted through the two optical filters, wherein
the wavelength detecting process includes detecting a wavelength of the laser light beam, on a basis of one of ratios of the two first electric current signals to the second electric current signal, the one being larger in change in relation to change in wavelength of the laser light beam at the target wavelength.

22. The control method for the wavelength-tunable laser element, according to claim 15, further comprising:
a first electric current signal outputting process of receiving a laser light beam and outputting two first electric current signals, the laser light beam being output from the wavelength-tunable laser element and thereafter transmitted through two optical filters having transmission spectra that are different from each other and that change periodically in relation to wavelength;
a second electric current signal outputting process of receiving a laser light beam and outputting a second electric current signal, the laser light beam being output from the wavelength-tunable laser element and thereafter not transmitted through the two optical filters; and
a wavelength detecting process of detecting a wavelength of the laser light beam, on a basis of one of ratios of the two first electric current signals to the second electric current signal, the one being larger in change in relation to change in wavelength of the laser light beam at the target wavelength, wherein
the wavelength corresponding control set values are each a ratio of one of the two first electric current signals to the second electric current signal, the ratio being set correspondingly to the intermediate wavelengths.

23. The control method for the wavelength-tunable laser element, according to claim 22, wherein the wavelength detecting process includes detecting a wavelength of the laser light beam, on a basis of one of ratios of the two first electric current signals to the second electric current signal, the one being larger in change in relation to change in wavelength of the laser light beam at the target wavelength.

24. The control method for the wavelength-tunable laser element, according to claim 15, wherein the control process includes controlling the electric power such that a difference between two adjacent ones of the wavelength corresponding control set values is equal to or less than a half width at half maximum of a spectrum of a combined reflection peak formed of a reflection peak of one of the two reflecting mirrors and a reflection peak of the other one of the two reflecting mirrors, the reflection peaks overlapping each other at the same wavelength.

25. The control method for the wavelength-tunable laser element, according to claim 24, wherein the control process includes controlling the electric power such that a difference between the two adjacent wavelength corresponding control set values is equal to or less than a half width at half maximum of an oscillation spectrum of a laser light beam output in a state where the spectrum of the combined reflection peak and a resonator mode of the laser resonator match each other.

26. A control method for a wavelength-tunable laser element and executed by a control unit comprising an arithmetic unit and a recording unit, the wavelength-tunable laser element including: a laser resonator formed of two reflecting mirrors having reflection spectra with periodic peaks on cycles different from each other in relation to wavelength; a gain unit arranged in the laser resonator; and plural control elements that control laser emission wavelength by being supplied with electric power, the control method comprising:
a control process of controlling the plural control elements to monotonously change the laser emission wavelength from a current laser emission wavelength to a target wavelength, wherein
the control process includes discretely changing the laser emission wavelength in steps that are each equal to or less than a narrower one of half widths at half maximum of reflection peaks of the two reflecting mirrors when monotonously changing the laser emission wavelength.

27. The control method for the wavelength-tunable laser element according to claim 26, wherein the control process includes controlling the electric power such that the steps each become equal to or less than a half width at half maximum of a spectrum of a combined reflection peak formed of a reflection peak of one of the two reflecting mirrors and a reflection peak of the other one of the two reflecting mirrors, the reflection peaks overlapping each other at the same wavelength.

28. The control method for the wavelength-tunable laser element, according to claim 27, wherein the control process includes controlling the electric power such that the steps each become equal to or less than a half width at half maximum of an oscillation spectrum of a laser light beam output in a state where the combined reflection peak and a resonator mode of the laser resonator match each other.
